(19) United States
(12) Patent Application Publication
(10) Pub. No.: US 2012/0120563 A1
(43) Pub. Date: May 17, 2012

(54) ELECTRONIC DEVICE WITH ROTATABLE SUPPORTER

(75) Inventor: JIN-SHI LAI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/981,569

(22) Filed: Dec. 30, 2010

(30) Foreign Application Priority Data
Nov. 17, 2010 (CN) 201010547928.3

(51) Int. Cl. H05K 7/00

(52) U.S. Cl. 361/679.01

(57) ABSTRACT

An electronic device includes a main body and a rotatable supporter. The main body includes a housing and an elastic element fixed to the inner surface of the housing. One end of the rotatable supporter connects to the housing. The rotatable supporter includes a shaft and a positioning element. The positioning element passes through the housing to contact the elastic element and includes at least two engaging surfaces. The rotatable supporter is connected to the housing through the shaft. When one of the engaging surfaces contacts the elastic element in parallel, the rotatable supporter is maintained at a position. When the rotatable supporter is rotated to deform the elastic element and make another engaging surfaces contacts the elastic element in parallel, the rotatable supporter is maintained at another position.

### BACKGROUND

1. Technical Field

The present disclosure relates to an electronic device with a rotatable supporter.

2. Description of Related Art

Generally, portable electronic devices, such as digital photo frames (DPF), have supporters that generally have only one position available to support the DPF, and users cannot adjust the supporter to obtain a different viewing angle according to personal preference.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is an isometric view of an electronic device when a rotatable supporter is folded to a main body of the electronic device, in accordance with an exemplary embodiment.

FIG. 2 is an exploded isometric view of the electronic device of FIG. 1.

FIG. 3 is an enlarged isometric view of the rotatable supporter of the electronic device of FIG. 1.

FIG. 4 is a cross-sectional view taken along line IV-IV of FIG. 1.

FIG. 5 is similar to FIG. 4, but showing the rotatable supporter rotated to another position to support the main body of the electronic device of FIG. 1.

### DETAILED DESCRIPTION

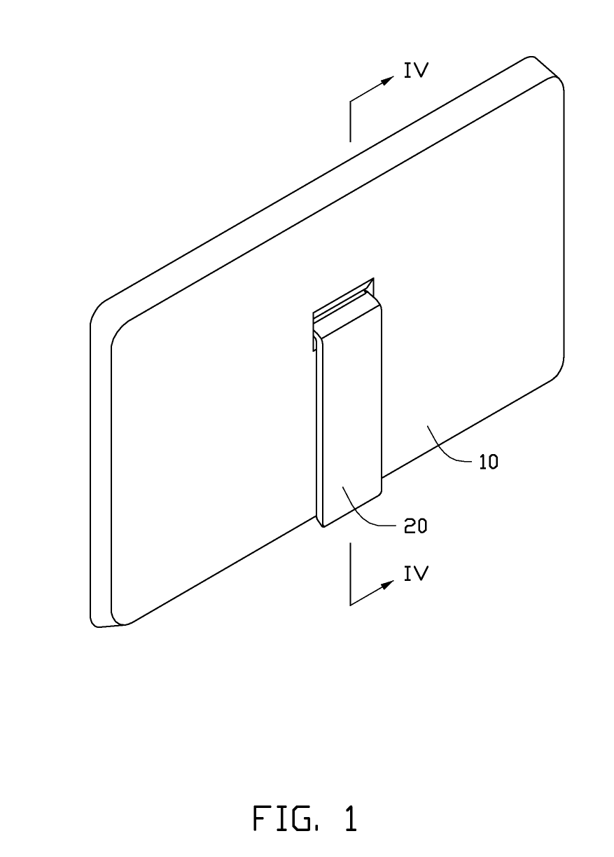

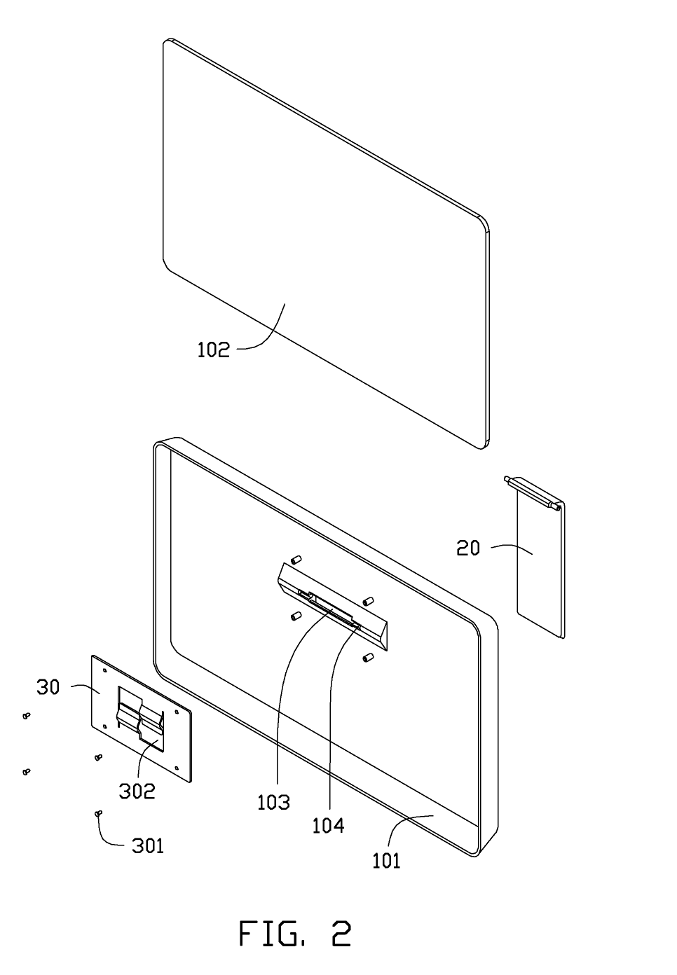

Referring to FIGS. 1 and 2, an electronic device 1 includes a main body 10 and a rotatable supporter 20. The main body 10 includes a housing 101 and other necessary components, such as a display unit 102. The device 1 further includes an elastic element 30 fixed to the inner surface of the housing 101 with one or more fasteners 301.

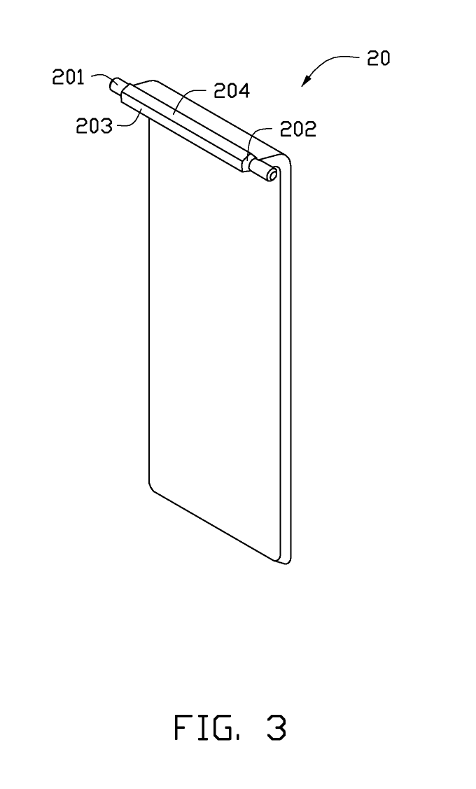

As shown in FIG. 3, one end of the rotatable supporter 20, which connects to the device 1, includes a shaft 201 and a positioning element 202. The positioning element 202 includes at least two engaging surfaces each adjacent two of which are at an angle to each other. In this exemplary embodiment, the positioning element 202 includes two engaging surfaces, namely, a first surface 203 and a second surface 204. The housing 101 includes a groove 102 and a through slot 103. The shaft 201 of the rotatable supporter 20 is placed into the groove 102 to connect the rotatable supporter 20 to the housing 101. The positioning element 202 passes through the through slot 103 to contact the elastic element 30.

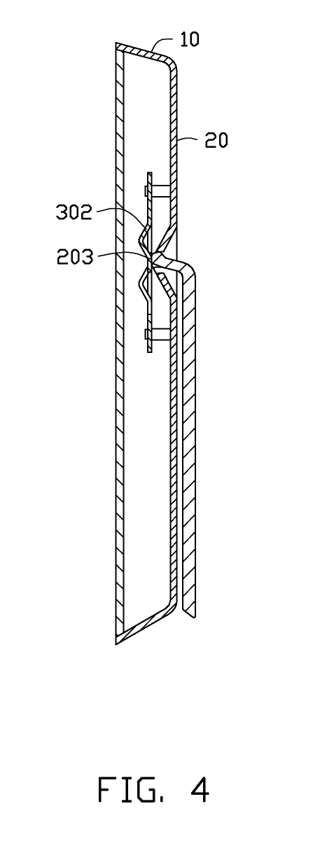

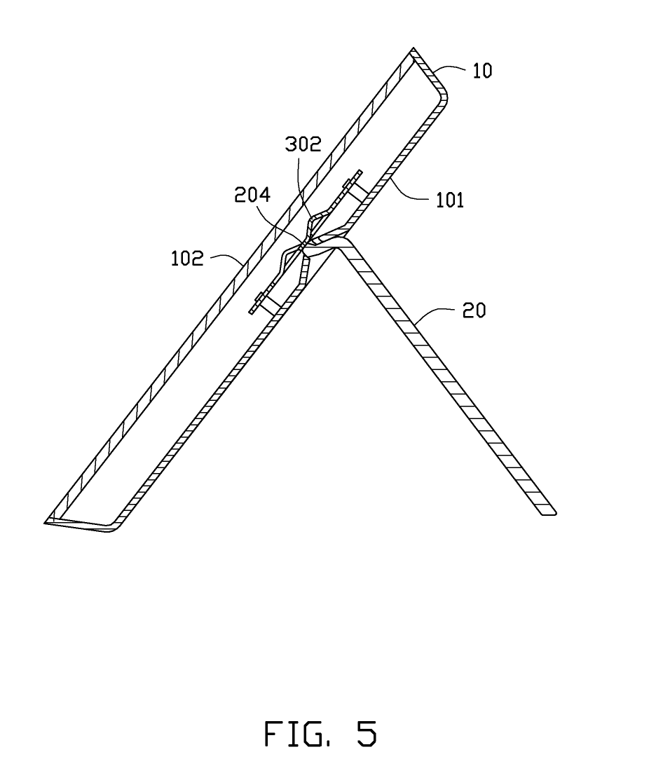

The elastic element 30 includes at least one elastic tab 302. When the first surface 203 contacts the elastic tab 302 in parallel, as shown in FIG. 4, the rotatable supporter 20 is folded to the main body 10. When the supporter 20 is rotated under an external force, the positioning element 202 deforms the elastic tab 302. When the supporter 20 is rotated to make the second surface 204 contact the elastic tab in parallel, as shown in FIG. 5, the supporter 20 is extended out the main body 10 and can maintain a predetermined angle with respect to the rotatable supporter 20, to support the body 10 at desired viewing angle.

In other embodiments, more than two surfaces can be configured for the positioning element 202 so that rotatable supporter 20 can be oriented and maintained in more than two positions to give users a plurality of viewing angles to choose from.

Although, the present disclosure has been specifically described on the basis of preferred embodiments, the disclosure is not to be construed as being limited thereto. Various changes or modifications may be made to the embodiment without departing from the scope and spirit of the disclosure.

What is claimed is:

1. An electronic device comprising
a main body comprising a housing;
an elastic element fixed to an inner surface of the housing;
a rotatable supporter, one end of which connects to the housing, comprising a shaft and a positioning element, the positioning element passing through the housing to contact the elastic element and comprising at least two engaging surfaces each adjacent two of which are at an angles to each other, the rotatable supporter being rotatably connected to the housing through the shaft;
wherein when one of the at least two engaging surfaces contacts the elastic element in parallel, the rotatable supporter maintains the main body in a predetermined angle with respect to the rotatable supporter, when the rotatable supporter is rotated to deform the elastic element and make another one of the at least two engaging surfaces contact the elastic element in parallel, the rotatable supporter maintains in another angle with respect to the main body.

2. The electronic device as described in claim 1, wherein the housing comprises a groove, the shaft is placed into the groove to connect the rotatable supporter to the housing.

3. The electronic device as described in claim 1, wherein the housing comprises a through slot, the positioning element passes through the through slot to contact the elastic element.

4. The electronic device as described in claim 1, wherein the elastic element comprises at least one elastic tab, the positioning element contacts the elastic tab; when the rotatable supporter is rotated, the elastic tab is deformed by the positioning element.

5. The electronic device as described in claim 1, wherein the number of the at least two engaging surfaces are two, when one of the two engaging surfaces contacts the elastic element, the rotatable supporter is folded to the housing, and when the other engaging surface of the two engaging surfaces contacts the elastic element, the rotatable supporter is extended out the main body and maintain a predetermined angle with respect to the rotatable support.
